(19) United States
(12) Patent Application Publication
(10) Pub. No.: US 2024/0079410 A1
(43) Pub. Date: Mar. 7, 2024

(54) SEMICONDUCTOR DEVICE

(71) Applicant: Kioxia Corporation, Tokyo (JP)

(72) Inventor: Tomoaki YABE, Tokyo (JP)

(73) Assignee: Kioxia Corporation, Tokyo (JP)

(21) Appl. No.: 18/078,862

(22) Filed: Dec. 9, 2022

(30) Foreign Application Priority Data
Sep. 2, 2022 (JP) 2022-140217

(51) Int. Cl. H01L 27/118

(52) U.S. Cl. CPC H01L 27/11807; H01L 2027/11853; H01L 2027/11881

(57) ABSTRACT

A semiconductor device according to embodiments includes: a first semiconductor layer having a first source region, a first drain region, and a first channel region; a second semiconductor layer having a second source region, a second drain region, and a second channel region; and a gate electrode that is formed to cover the first channel region and the second channel region with a gate insulating film interposed. The semiconductor device includes a first CMOS circuit and a second CMOS circuit each formed of the combination of a first conductive type MOS having the first semiconductor layer and a second conductive type MOS having the second semiconductor layer. The first semiconductor layer is stacked in a (2n−1)^{th} layer. The second semiconductor layer is stacked in a 2n^{th} layer (1≤n≤N, N≥2, and n and N are integers).

### CROSS REFERENCE TO RELATED APPLICATIONS

This application is based upon and claims the benefit of priority from prior Japanese Patent Application No. P 2022-140217 filed on Sep. 2, 2022, the entire contents of which are incorporated herein by reference.

### FIELD

Embodiments described herein relate to a semiconductor device.

### BACKGROUND

Conventionally, it has been known that, due to efforts for miniaturization of semiconductor devices, NMOS and PMOS transistors are stacked, and semiconductor devices are formed of three-dimensional circuits. However, even if one layer of an NMOS transistor and one layer of a PMOS transistor are stacked on each other, there is a risk that the device density per substrate unit area may be small.

### BRIEF DESCRIPTION OF THE DRAWINGS

FIG. 1 is a planar pattern configuration diagram of a semiconductor device according to a first embodiment.

FIG. 2 is a cross-sectional view taken along line A1-A1 of FIG. 1.

FIG. 3A is a planar pattern configuration diagram of a first semiconductor layer.

FIG. 3B is a planar pattern configuration diagram of a first semiconductor layer.

FIG. 3C is a planar pattern configuration diagram of a second semiconductor layer.

FIG. 3D is a planar pattern configuration diagram of a second semiconductor layer.

FIG. 4 is a diagram showing an equivalent circuit of a semiconductor device according to a first embodiment.

FIG. 5 is a planar pattern configuration diagram of a semiconductor device according to a second embodiment.

FIG. 6 is a cross-sectional view taken along line A2-A2 of FIG. 5.

FIG. 7 is a cross-sectional view taken along line A3-A3 of FIG. 5.

FIG. 8 is a planar pattern configuration diagram of a semiconductor device according to a third embodiment.

FIG. 9 is a cross-sectional view taken along line A4-A4 of FIG. 8.

FIG. 10 is a planar pattern configuration diagram of a semiconductor device according to a fourth embodiment.

FIG. 11 is a cross-sectional view taken along line A5-A5 of FIG. 10.

FIG. 12 is a cross-sectional view taken along line A6-A6 of FIG. 10.

FIG. 13 is a planar pattern configuration diagram of a semiconductor device according to a modified example of a fourth embodiment.

FIG. 14 is a cross-sectional view taken along line A7-A7 of FIG. 13.

FIG. 15 is a cross-sectional view taken along line A8-A8 of FIG. 13.

FIG. 16 is a cross-sectional view taken along line A9-A9 of FIG. 13.

FIG. 17 is a cross-sectional view taken along line B1-B1 of FIG. 13.

FIG. 18 is a diagram showing an equivalent circuit of a semiconductor device according to a modified example of a fourth embodiment.

FIG. 19 is a planar pattern configuration diagram of a semiconductor device according to a fifth embodiment.

FIG. 20 is a cross-sectional view taken along line A10-A10 of FIG. 19.

FIG. 21 is a diagram showing an equivalent circuit of a semiconductor device according to a fifth embodiment.

FIG. 22 is a planar pattern configuration diagram of a semiconductor device according to a sixth embodiment.

FIG. 23 is a cross-sectional view taken along line A11-A11 of FIG. 22.

FIG. 24 is a diagram showing an equivalent circuit of a semiconductor device according to a sixth embodiment.

FIG. 25 is a planar pattern configuration diagram of a semiconductor device according to a seventh embodiment.

FIG. 26 is a cross-sectional view taken along line A12-A12 of FIG. 25.

FIG. 27 is a planar pattern configuration diagram of a semiconductor device according to an eighth embodiment.

FIG. 28 is a cross-sectional view taken along line A13-A13 of FIG. 27.

### DETAILED DESCRIPTION

Next, certain embodiments will now be described with reference to the drawings. In the description of the following drawings to be explained, identical or similar parts are denoted by identical or similar reference numerals, and therefore a description thereof is omitted. However, it should be noted that the drawings are schematic.

Moreover, the embodiments described hereinafter merely exemplify the device and method for materializing the technical idea, and the embodiments do not specify the material, shape, configuration, placement, and the like of each component part as the following. The embodiments may be changed without departing from the spirit or scope of claims.

The present embodiment provides a semiconductor device that enhances the device density per substrate unit area and the degree of freedom of the layout.

Certain embodiments provide a semiconductor device including: a first semiconductor layer having a first source region, a first drain region, and a first channel region; a second semiconductor layer having a second source region, a second drain region, and a second channel region; and a gate electrode that is formed to cover the first channel region and the second channel region with a gate insulating film interposed. The semiconductor device further includes a first CMOS circuit and a second CMOS circuit each formed of the combination of a first conductive type MOS having the first semiconductor layer and a second conductive type MOS having the second semiconductor layer. The first semiconductor layer is stacked in a (2n−1)^{th} layer. The second semiconductor layer is stacked in a 2n^{th} layer (1≤n≤N, N≥2, and n and N are integers). For a certain i (1≤i≤N), in the first CMOS circuit, the gate electrode is electrically connected in common with at least the first conductive type MOS of the first semiconductor layer of a (2i−1)^{th} layer and the second conductive type MOS of the second semiconductor layer of a 2i^{th} layer. In the second CMOS circuit, the gate electrode is electrically connected in common with at least the second conductive type MOS of the second semiconductor layer of the 2i^{th} layer and the first conductive type MOS of the first semiconductor layer of a (2i+1)^{th} layer.

### First Embodiment

### (Configuration of Semiconductor Device)

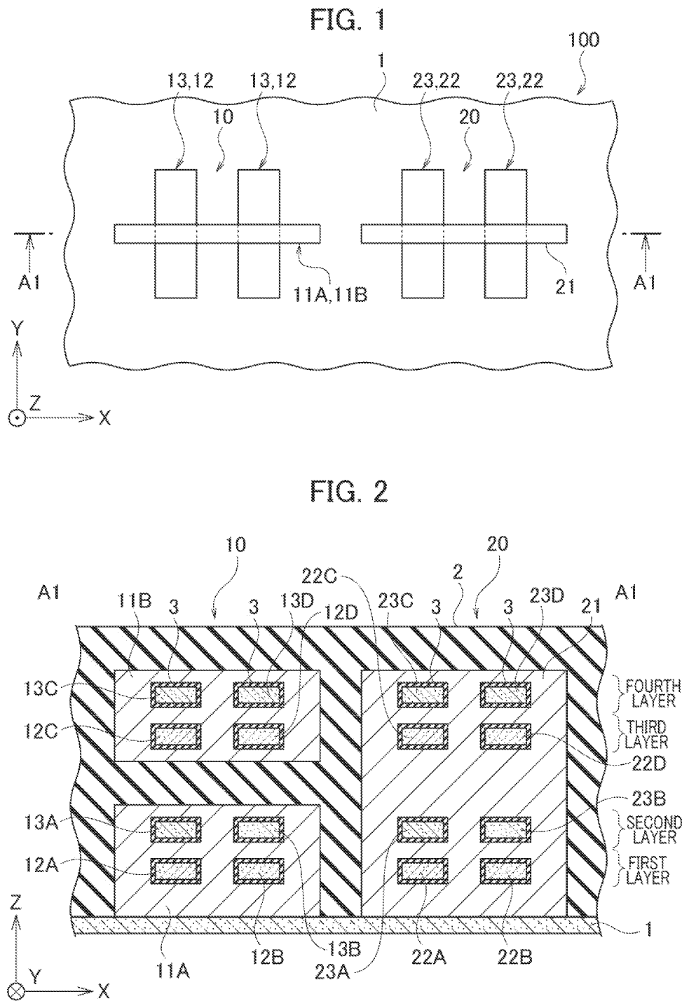

A semiconductor device 100 according to a first embodiment will be described. In the following description, an XYZ coordinate system, which is an example of a Cartesian coordinate system, is used. That is, the plane parallel to the surface of a substrate 1 forming the semiconductor device 100 is defined as an XY plane, and the direction perpendicular to the XY plane is defined as a Z direction. In addition, X and Y axes are two perpendicular directions in the XY plane. FIG. 1 is a top view and does not show an interlayer insulation film 2.

As shown in FIGS. 1 and 2, the semiconductor device 100 has a first semiconductor layer (12 and 22), a second semiconductor layer (13 and 23), and a gate electrode (11A, 11B, and 21). The semiconductor device also has a first CMOS (CMOS: complementary CMOS) circuit 10 and a second CMOS circuit 20, which are formed of the combination of a first conductive metal oxide semiconductor (MOS) and a second conductive type MOS. The semiconductor device may have the substrate 1 and the interlayer insulation film 2. In the following description, a first semiconductor layer (12A, 12B, 22A, and 22B) of the first layer and a first semiconductor layer (12C, 12D, 22C, and 22D) of the third layer shown in FIG. 2 are collectively referred to as the first semiconductor layer (12 and 22). A second semiconductor layer (13A, 13B, 23A, and 23B) of the second layer and a second semiconductor layer (13C, 13D, 23C, and 23D) of the fourth layer shown in FIG. 2 are also collectively referred to as the second semiconductor layer (13 and 23).

The substrate 1 includes a semiconductor substrate, for example. The substrate 1 may have an oxide film.

As shown in FIG. 2, the interlayer insulation film 2 is disposed on the substrate 1. The interlayer insulation film 2 is arranged to cover the gate electrode (11A, 11B, and 21), the first semiconductor layer (12 and 22), and the second semiconductor layer (13 and 23).

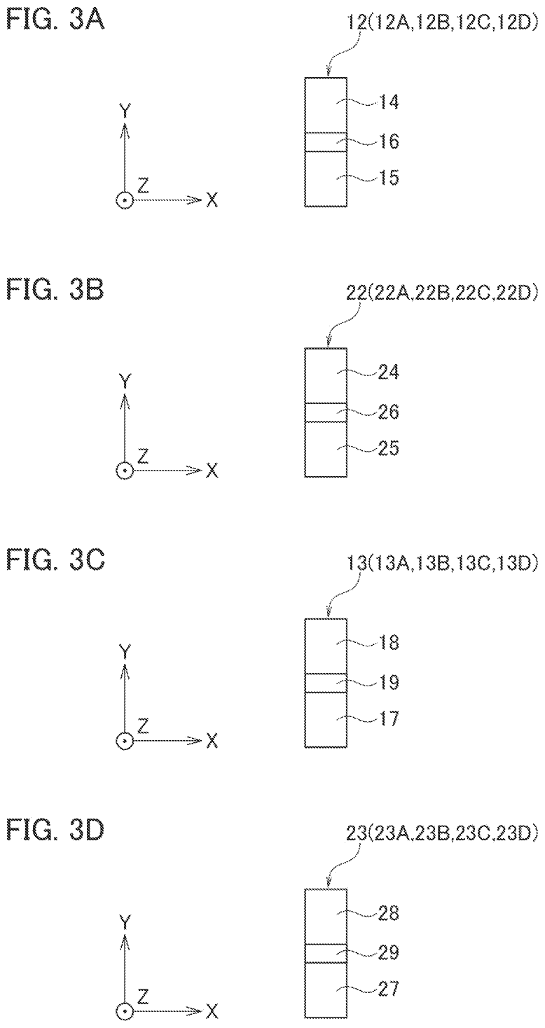

As shown in FIGS. 3A and 3B, the first semiconductor layer 12 (12A to 12D) and the first semiconductor layer 22 (22A to 22D) each have a first source region (14 and 24), a first drain region (15 and 25), and a first channel region (16 and 26).

As shown in FIGS. 3C and 3D, the second semiconductor layer 13 (13A to 13D) and the second semiconductor layer 23 (23A to 23D) each have a second source region (17 and 27), a second drain region (18 and 28), and a second channel region (19 and 29).

As shown in FIG. 2, the first semiconductor layer (12A, 12B, 22A, and 22B) is arranged in the first layer stacked vertical to the surface of the substrate 1, for example. Further, the first semiconductor layer (12C, 12D, 22C, and 22D) is arranged in the third layer stacked vertical to the surface of the substrate 1, for example. That is, the first semiconductor layer (12 and 22) is stacked in the (2n−1)^{th} layer (1≤n≤N, N≥2, and n and N are integers).

As shown in FIG. 2, the second semiconductor layer (13A, 13B, 23A, and 23B) is arranged in the second layer stacked vertical to the surface of the substrate 1, for example. Further, the second semiconductor layer (13C, 13D, 23C, and 23D) is arranged in the fourth layer stacked vertical to the surface of the substrate 1, for example. That is, the second semiconductor layer (13 and 23) is stacked in the 2n^{th} layer (1≤n≤N, N≥2, and n and N are integers). In FIG. 2, there are four stacked layers of the first semiconductor layer (12 and 22) and the second semiconductor layer (13 and 23), but there may be four or more stacked layers. In the semiconductor device 100, the first semiconductor layer (12 and 22) may be stacked in the first and third layers, the second semiconductor layer (13 and 23) may be stacked in the second layer, and there may be three stacked layers.

The first conductive type MOS has the first semiconductor layer (12 and 22). Specifically, the first conductive type MOS may be a P-channel MOS (PMOS), for example.

The second conductive type MOS has the second semiconductor layer (13 and 23). Specifically, the second conductive type MOS may be an N-channel MOS (NMOS), for example.

As shown in FIG. 2, the gate electrode (11A, 11B, and 21) is disposed on the substrate 1. The gate electrode (11A, 11B, and 21) is formed to cover the first channel region (16 and 26) and the second channel region (19 and 29) with a gate insulating film 3 interposed. Specifically, a gate electrode 11A is formed to cover a first channel region 16 of a first semiconductor layer (12A and 12B) and a second channel region 19 of a second semiconductor layer (13A and 13B). A gate electrode 11B is formed to cover the first channel region 16 of a first semiconductor layer (12C and 12D) and the second channel region 19 of a second semiconductor layer (13C and 13D). A gate electrode 21 is formed to cover a first channel region 26 of a first semiconductor layer (22A to 22D) and a second channel region 29 of a second semiconductor layer (23A to 23D).

The gate electrode 11B is spaced apart from the gate electrode 11A and the gate electrode 21.

The gate electrode 21 is spaced apart from the gate electrode 11A and the gate electrode 11B.

The first CMOS circuit 10 and the second CMOS circuit are each formed of the combination of the first conductive type MOS and the second conductive type MOS.

The first CMOS circuit 10 has the gate electrode 11A and the gate electrode 11B. For a certain i (1≤i≤N), in the first CMOS circuit 10, the gate electrode (11A and 11B) is electrically connected in common with the first conductive type MOS of the first semiconductor layer 12 of at least the (2i−1)^{th} layer (that is, 1, 3, 5 . . . (2i−1^{th} layer)) and the second conductive type MOS of the second semiconductor layer 13 of the 2i^{th} layer (that is, 2, 4, 6 . . . 2i^{th} layer). Specifically, in the first CMOS circuit 10, the gate electrode 11A is electrically connected in common with the PMOS as the first conductive type MOS of the first semiconductor layer (12A and 12B) of the first layer and the NMOS as the second conductive type MOS of the second semiconductor layer (13A and 13B) of the second layer, for example. Similarly, in the first CMOS circuit 10, the gate electrode 11B is electrically connected in common with the PMOS as the first conductive type MOS of the first semiconductor layer (12C and 12D) of the third layer and the NMOS as the second conductive type MOS of the second semiconductor layer (13C and 13C) of the fourth layer, for example.

The second CMOS circuit 20 has the gate electrode 21. For a certain i (1≤n≤N), in the second CMOS circuit 20, the gate electrode 21 is electrically connected in common with the second conductive type MOS of the second semiconductor layer 23 of at least the 2i^{th} layer and the first conductive type MOS of the first semiconductor layer 22 of the (2i+1)^{th} layer (that is, 3, 5, 7 . . . (2i+1)^{th} layer). Specifically, in the second CMOS circuit 20, the gate electrode 21 is electrically connected in common with the NMOS as the second conductive type MOS of the second semiconductor layer (23A and 23B) of the second layer and the PMOS as the first conductive type MOS of the first semiconductor layer (22C and 22D) of the third layer, for example.

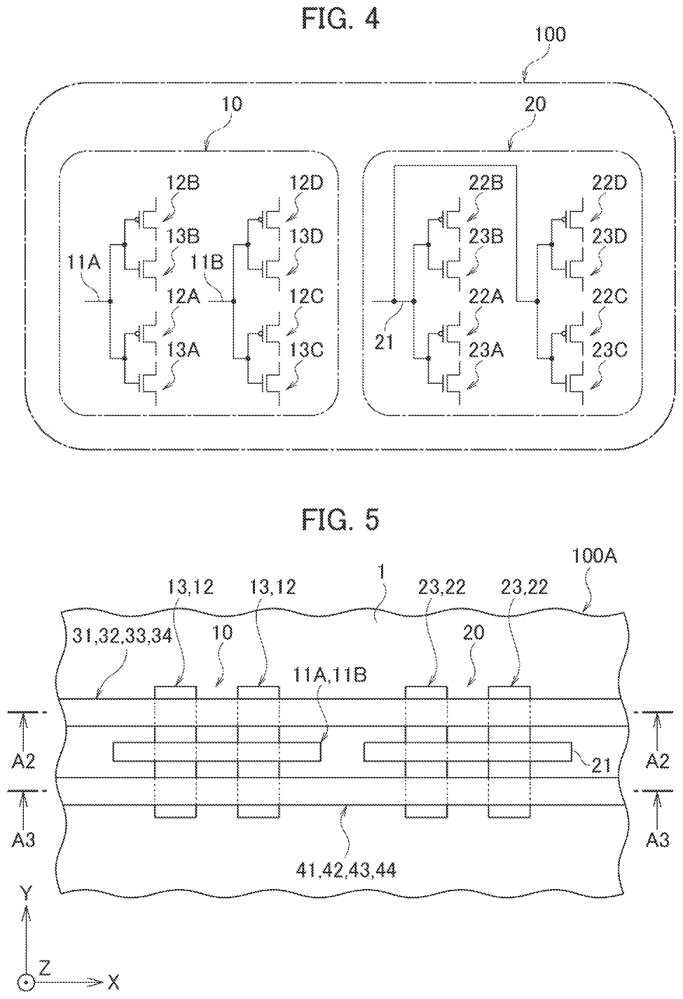

Next, an equivalent circuit of the semiconductor device 100 will be described with reference to FIG. 4.

The equivalent circuit of the semiconductor device 100 is represented by using the first CMOS circuit 10 and the second CMOS circuit 20 as shown in FIG. 4. In the following description, a circuit structure including a first semiconductor layer 12A and a second semiconductor layer 13A is also referred to as the first circuit structure. A circuit structure including a first semiconductor layer 12B and a second semiconductor layer 13B is also referred to as the second circuit structure. A circuit structure including a first semiconductor layer 12C and a second semiconductor layer 13C is also referred to as the third circuit structure. A circuit structure including a first semiconductor layer 12D and a second semiconductor layer 13D is also referred to as the fourth circuit structure. A circuit structure including a first semiconductor layer 22A and a second semiconductor layer 23A is also referred to as the fifth circuit structure. A circuit structure including a first semiconductor layer 22B and a second semiconductor layer 23B is also referred to as the sixth circuit structure. A circuit structure including a first semiconductor layer 22C and a second semiconductor layer 23C is also referred to as the seventh circuit structure. A circuit structure including a first semiconductor layer 22D and a second semiconductor layer 23D is also referred to as the eighth circuit structure.

The first CMOS circuit 10 can be represented by using the first circuit structure in which the gate electrode 11A is electrically connected in common with the PMOS as the first conductive type MOS having the first semiconductor layer 12A of the first layer and the NMOS as the second conductive type MOS having the second semiconductor layer 13A of the second layer, for example. In addition, the first CMOS circuit 10 can be represented by using the second circuit structure in which the gate electrode 11A is electrically connected in common with the PMOS as the first conductive type MOS having the first semiconductor layer 12B of the first layer and the NMOS as the second conductive type MOS having the second semiconductor layer 13B of the second layer. Furthermore, the circuit can be represented by using a circuit structure in which the gate electrodes 11A of the first and second circuit structures are electrically connected in common.

Similarly, the first CMOS circuit 10 can be represented by using the third circuit structure in which the gate electrode 11B is electrically connected in common with the PMOS as the first conductive type MOS having the first semiconductor layer 12C of the third layer, and the NMOS as the second conductive type MOS having the second semiconductor layer 13C of the fourth layer, for example. Moreover, the first CMOS circuit 10 can be represented by using the fourth circuit structure in which the gate electrode 11B is electrically connected in common with the PMOS as the first conductive type MOS having the first semiconductor layer 12D of the third layer and the NMOS as the second conductive type MOS having the second semiconductor layer 13D of the fourth layer, for example. Furthermore, the circuit can be represented by using a structure in which the gate electrodes 11B of the third and fourth circuit structures are electrically connected in common.

The second CMOS circuit 20 can be represented by using the fifth circuit structure in which the gate electrode 21 is electrically connected in common with the PMOS as the first conductive type MOS having the first semiconductor layer 22A of the first layer and the NMOS as the second conductive type MOS having the second semiconductor layer 23A of the second layer, for example. Further, the second CMOS circuit 20 can be represented by using the sixth circuit structure in which the gate electrode 21 is electrically connected in common with the PMOS as the first conductive type MOS having the first semiconductor layer 22B of the first layer, and the NMOS as the second conductive type MOS having the second semiconductor layer 23B of the second layer, for example. Furthermore, the circuit can be represented by using a circuit structure in which the gate electrodes 21 of the fifth and sixth circuit structures are electrically connected in common.

The second CMOS circuit 20 can be represented by using the seventh circuit structure in which the gate electrode 21 is electrically connected in common with the PMOS as the first conductive type MOS having the first semiconductor layer 22C of the third layer, and the NMOS as the second conductive type MOS having the second semiconductor layer 23C of the fourth layer, for example. In addition, the second CMOS circuit 20 can be represented by using the eighth circuit structure in which the gate electrode 21 is electrically connected in common with the PMOS as the first conductive type MOS having the first semiconductor layer 22D of the third layer, and the NMOS as the second conductive type MOS having the second semiconductor layer 23D of the fourth layer, for example. The circuit can also be represented by using a structure in which the gate electrodes 21 of the seventh and eighth circuit structures are electrically connected in common. Furthermore, the circuit can be represented by using a structure in which the gate electrodes 21 of the fifth, sixth, seventh, and eighth circuit structures are electrically connected in common.

As shown in FIG. 4, the semiconductor device 100 is able to have a CMOS basic gate configuration such as an inverter circuit, a two-input NAND circuit, and a two-input NOR circuit, by having the circuit structure of a CMOS circuit that is the basis of a logic circuit, for example. That is, the semiconductor device 100 can enhance the degree of freedom of the layout by reducing wiring that electrically connects the gates of each CMOS structure.

### (Effect of First Embodiment)

As described above, according to the first embodiment, three or more layers of the first conductive type MOS and the second conductive type MOS are alternately stacked. Focusing on a certain first semiconductor layer or the second semiconductor layer, a gate electrode is commonly connected with the first semiconductor layer or the second semiconductor layer on or below the certain first semiconductor layer or the second semiconductor layer. This can enhance the device density per substrate unit area and the degree of freedom of the layout.

### Second Embodiment

### (Configuration of Semiconductor Device)

A semiconductor device 100A according to a second embodiment will be described. FIG. 5 is a top view and does not show the interlayer insulation film 2.

As shown in FIG. 5, the semiconductor device 100A further includes a first power supply wiring layer (31 and 33), a second power supply wiring layer (32 and 34), and first to fourth signal wiring layers (41 to 44) in addition to the components of the semiconductor device 100 according to the first embodiment. Since other configurations are the same as those of the semiconductor device 100 according to the first embodiment, the explanation thereof is omitted.

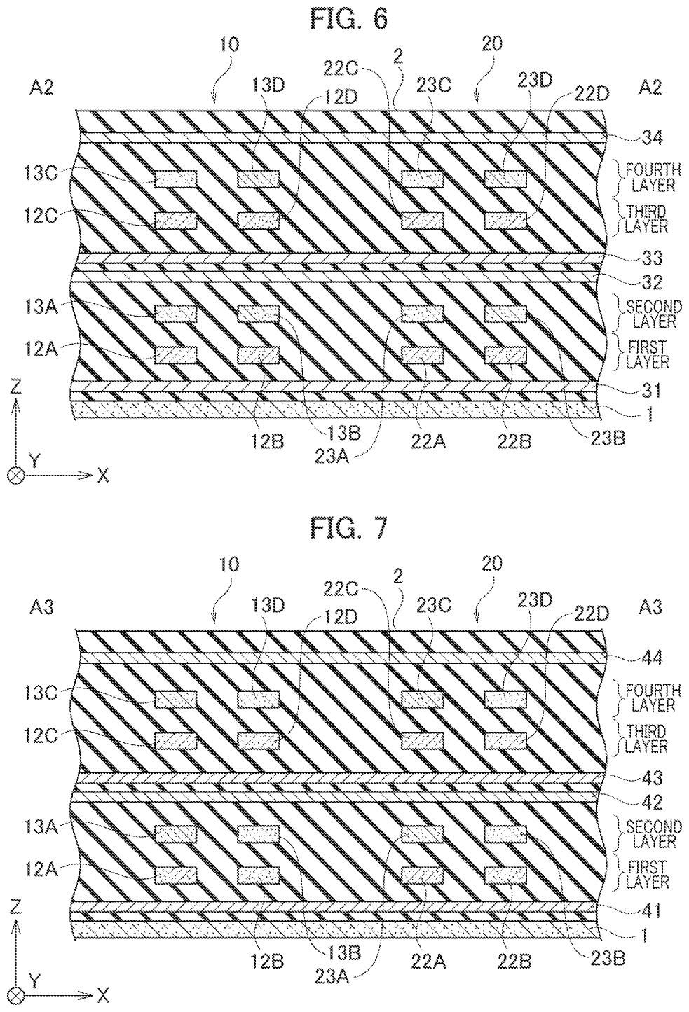

As shown in FIG. 6, a first power supply wiring layer (31 and 33) is arranged below the first semiconductor layers (12 and 22) of the first and third layers in a direction perpendicular to the first semiconductor layers (12 and 22), for example. Specifically, the first power supply wiring layer 31 is arranged below the first source region (14 and 24) of the first semiconductor layer (12A, 12B, 22A, and 22B) of the first layer, for example. Further, a first power supply wiring layer 33 is arranged below the first source region (14 and 24) of the first semiconductor layer (12C, 12D, 22C, and 22D) of the third layer, for example. The first power supply wiring layer (31 and 33) may be VDD wiring, for example.

The second power supply wiring layer (32 and 34) is arranged above the second semiconductor layers (13 and 23) of the second and fourth layers in a direction perpendicular to the second semiconductor layers (13 and 23), for example. Specifically, the second power supply wiring layer 32 is arranged above the second drain region (18 and 28) of the second semiconductor layer (13A, 13B, 23A, and 23B) of the second layer, for example. Further, the second power supply wiring layer 34 is arranged above the second drain region (18 and 28) of the second semiconductor layer (13C, 13D, 23C, and 23D) of the fourth layer, for example. The second power supply wiring layer (32 and 34) may be VSS wiring, for example.

As shown in FIG. 7, the first and third signal wiring layers (41 and 43) are arranged below the first semiconductor layers (12 and 22) of the first and third layers in a direction perpendicular to the first semiconductor layers (12 and 22), for example. Specifically, a first signal wiring layer 41 is arranged below the first drain region (15 and 25) of the first semiconductor layer (12A, 12B, 22A, and 22B) of the first layer, for example. Further, a third signal wiring layer 43 is arranged below the first drain region (15 and 25) of the first semiconductor layer (12C, 12D, 22C, and 22D) of the third layer, for example.

The second and fourth signal wiring layers (42 and 44) are arranged above the second semiconductor layers (13 and 23) of the second and fourth layers in a direction perpendicular to the second semiconductor layers (13 and 23), for example. Specifically, a second signal wiring layer 42 is arranged above the second source region (17 and 27) of the second semiconductor layer (13A, 13B, 23A, and 23B) of the second layer, for example. Further, a fourth signal wiring layer 44 is arranged above the second source region (17 and 27) of the second semiconductor layer (13C, 13D, 23C, and 23D) of the fourth layer, for example.

### (Effect of Second Embodiment)

As described above, according to the second embodiment, three or more layers of the first conductive type MOS and the second conductive type MOS are alternately stacked. Focusing on a certain first semiconductor layer or the second semiconductor layer, a gate electrode is commonly connected with the first semiconductor layer or the second semiconductor layer on or below the certain first semiconductor layer or the second semiconductor layer. This can enhance the device density per substrate unit area and the degree of freedom of the layout.

Furthermore, according to the second embodiment, by arranging the first power supply wiring layer and the second power supply wiring layer above or below the first semiconductor layer or the second semiconductor layer, a VDD potential and a VSS potential can be easily connected to both the first semiconductor layer and the second semiconductor layer. Accordingly, it is possible to enhance the degree of freedom of the layout.

### Third Embodiment

### (Configuration of Semiconductor Device)

A semiconductor device 100B according to a third embodiment will be described. FIG. 8 is a top view and does not show the interlayer insulation film 2.

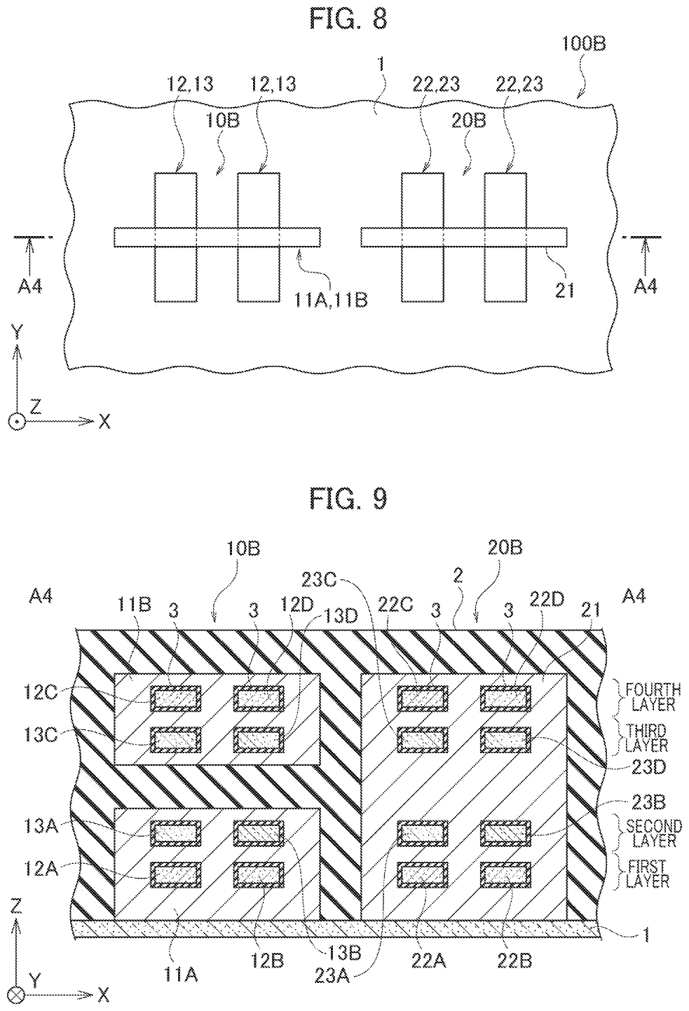

In the semiconductor device 100B, while the first semiconductor layers (12 and 22) according to the first embodiment are arranged in the first and third layers, the first semiconductor layers (12 and 22) of the third embodiment are arranged in the first and fourth layers, as shown in FIG. 9. Further, in the semiconductor device 100B, while the second semiconductor layers (13 and 23) of the first embodiment are arranged in the second and fourth layers, the second semiconductor layers (13 and 23) of the third embodiment are arranged in the second and third layers. The semiconductor device may have the substrate 1 and the interlayer insulation film 2. A first CMOS circuit 10B is another example of the first CMOS circuit 10. A second CMOS circuit 20B is another example of the second CMOS circuit 20. Other configurations of the semiconductor device of the third embodiment are the same as those of the semiconductor device 100 according to the first embodiment, and therefore descriptions thereof are omitted. In addition, an equivalent circuit of the semiconductor device 100B is the same as that of the semiconductor device 100 according to the first embodiment, and therefore descriptions thereof are omitted.

As shown in FIG. 9, the first semiconductor layer (12A, 12B, 22A, and 22B) is stacked vertical to the surface of the substrate 1 and arranged in the first layer. Further, the first semiconductor layer (12C, 12D, 22C, and 22D) is stacked vertical to the surface of the substrate 1 and arranged in the fourth layer. In FIG. 9, the stacked layers of the first semiconductor layer (12 and 22) and the second semiconductor is layer (13 and 23) are four layers, but the stacked layers may have four or more layers. That is, the first semiconductor layers (12 and 22) are stacked in the (4n−3)^{th} and 4n^{th} layers (1≤n≤N, N≥1, and n and N are integers).

As shown in FIG. 9, the second semiconductor layer (13A, 13B, 23A, and 23B) is arranged in the second layer stacked vertical to the surface of the substrate 1. Further, the second semiconductor layer (13C, 13D, 23C, and 23D) is arranged in the third layer stacked vertical to the surface of the substrate 1. That is, the second semiconductor layers (13 and 23) are stacked in the (4n−2)^{th} and (4n−1)^{th} layers (1≤n≤N, N≥1, and n and N are integers). In FIG. 9, there are four stacked layers of the first semiconductor layer (12 and 22) and the second semiconductor layer (13 and 23), but there may be four or more stacked layers. In the semiconductor device 100, the first semiconductor layer (12 and 22) may be stacked in the first layer, and the second semiconductor layers (13 and 23) may be stacked in the second and third layers, so that there are three stacked layers.

The first CMOS circuit 10B and the second CMOS circuit 20B are each formed of a combination of the first conductive type MOS as a PMOS and the second conductive type MOS as an NMOS.

The first CMOS circuit 10B has the gate electrode 11A and the gate electrode 11B. For a certain i (1≤i≤N), in the first CMOS circuit 10B, the gate electrode (11A and 11B) is electrically connected in common with the first conductive type MOS of the first semiconductor layer 12 of at least the is (4i−3)^{th} layer (that is, 1, 5, 9 . . . 4i−3^{th} layer) and the second conductive type MOS of the second semiconductor layer 13 of at least the (4i−2)^{th} layer (that is, 2, 6, 10 . . . 4i−2^{th} layer). Specifically, in the first CMOS circuit 10B, the gate electrode 11A is electrically connected in common with the PMOS as the first conductive type MOS of the first semiconductor layer (12A and 12B) of the first layer and the NMOS as the second conductive type MOS of the second semiconductor layer (13A and 13B) of the second layer, for example.

The second CMOS circuit 20B has the gate electrode 21. For a certain i (1≤i≤N), in the second CMOS circuit 20B, the gate electrode 21 is electrically connected in common with at least the second conductive type MOS of the second semiconductor layer 23 of the (4i−2)^{th} layer and the second conductive type MOS of the second semiconductor layer 23 of the (4i−1)^{th} layer (that is, 3, 7, 11 . . . 4i−1th layer). Specifically, in the second CMOS circuit 20B, the gate electrode 21 is electrically connected in common with the NMOS as the second conductive type MOS of the second semiconductor layer (23A and 23B) of the second layer and the NMOS as the second conductive type MOS of the second semiconductor layer (23C and 23D) of the third layer, for example. That is, in the adjacent layers of the (4i−2) to and (4i−1)^{th} layers, the second CMOS circuit 20B is formed of the same conductive type MOS.

### (Effect of Third Embodiment)

As described above, according to the third embodiment, three or more layers of the first conductive type MOS and the second conductive type MOS are alternately stacked. Focusing on a certain first semiconductor layer or second semiconductor layer, the gate electrode is commonly connected with a first semiconductor layer or a second semiconductor layer on or below the certain first semiconductor layer or second semiconductor layer. This can enhance the device density per substrate unit area and the degree of freedom of the layout.

### Fourth Embodiment

### (Configuration of Semiconductor Device)

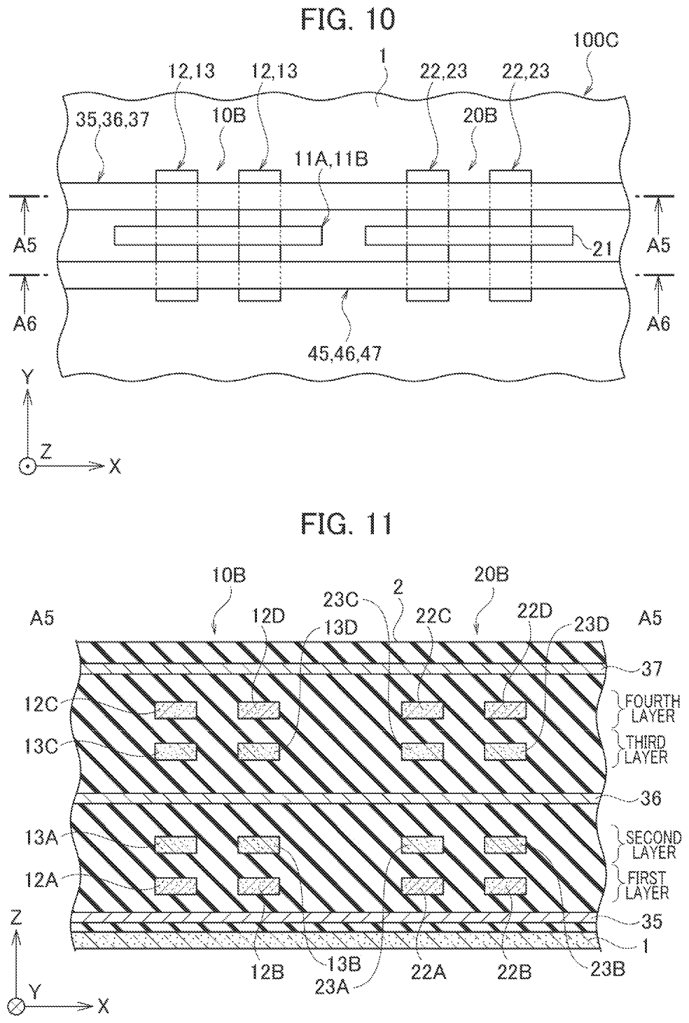

A semiconductor device 100C according to a fourth embodiment will be described. FIG. 10 is a top view and does not show the interlayer insulation film 2.

As shown in FIG. 10, the semiconductor device 100C according to the fourth embodiment further includes a first power supply wiring layer (35 and 37), a second power supply wiring layer 36, and first to third signal wiring layers (45 to 47) in addition to the elements of the semiconductor device 100B according to the third embodiment. Other configurations of the semiconductor device according to the fourth embodiment are the same as those of the semiconductor device 100B according to the third embodiment, and therefore a description thereof is omitted.

As shown in FIG. 11, a first power supply wiring layer is arranged below the first semiconductor layer (12 and 22) of the first layer in a direction perpendicular to the first semiconductor layer (12 and 22), for example. Further, a first power supply wiring layer 37 is arranged above the first semiconductor layer (12 and 22) of the fourth layer in a direction perpendicular to the first semiconductor layer (12 and 22), for example. Specifically, the first power supply wiring layer 35 is arranged below the first source region (14 and 24) of the first semiconductor layer (12A, 12B, 22A, and 22B) of the first layer, for example. Further, the first power supply wiring layer 37 is arranged above the first source region (14 and 24) of the first semiconductor layer (12C, 12D, 22C, and 22D) of the fourth layer, for example. The first power supply wiring layer (35 and 37) may be VDD wiring, for example.

The second power supply wiring layer 36 is interposed between the second semiconductor layers (13 and 23) of the second and third layers and is arranged in a direction perpendicular to the second semiconductor layers (13 and 23), for example. Specifically, the second power supply wiring layer 36 is interposed between the second drain region (18 and 28) of the second semiconductor layer (13A, 13B, 23A, and 23B) of the second layer and the second drain region (18 and 28) of the second semiconductor layer (13C, 13D, 23C, and 23D) of the third layer, for example. The second power supply wiring layer 36 may be VSS wiring, for example.

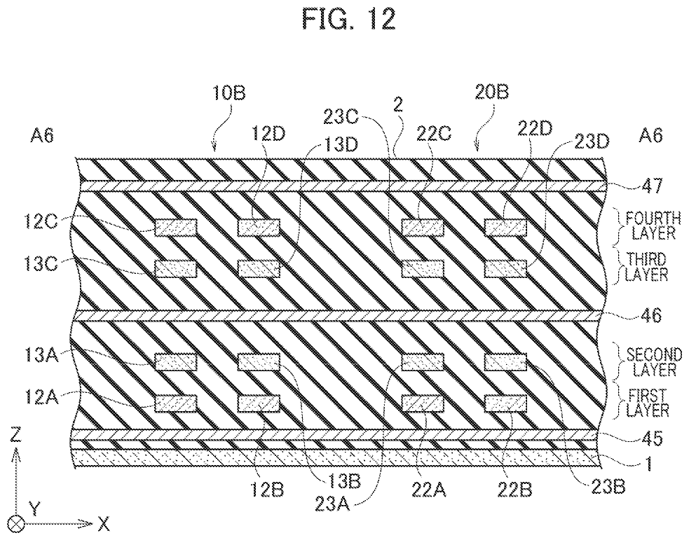

As shown in FIG. 12, a first signal wiring layer 45 is arranged below the first semiconductor layer (12 and 22) of the first layer in a direction perpendicular to the first semiconductor layer (12 and 22), for example. Further, the third signal wiring layer 47 is arranged above the first semiconductor layer (12 and 22) of the fourth layer in a direction perpendicular to the first semiconductor layer (12 and 22), for example. Specifically, the first signal wiring layer 45 is arranged below the first drain region (15 and 25) of the first semiconductor layer (12A, 12B, 22A, and 22B) of the first layer, for example. Further, a third signal wiring layer 47 is arranged above the first drain region (15 and 25) of the first semiconductor layer (12C, 12D, 22C, and 22D) of the fourth layer, for example.

The second signal wiring layer 46 is interposed between the second semiconductor layers (13 and 23) of the second and third layers and is arranged in a direction perpendicular to the second semiconductor layers (13 and 23), for example. Specifically, the second signal wiring layer 46 is interposed between the second source region (17 and 27) of the second semiconductor layer (13A, 13B, 23A, and 23B) of the second layer and the second source region (17 and 27) of the second semiconductor layer (13C, 13D, 23C, and 23D) of the third layer, for example.

### (Effect of Fourth Embodiment)

As described above, according to the fourth embodiment, three or more layers of the first conductive type MOS and the second conductive type MOS are alternately stacked. Focusing on a certain first semiconductor layer or second semiconductor layer, the gate electrode is commonly connected with a first semiconductor layer or second semiconductor layer on or below the certain first semiconductor layer or second semiconductor layer. This can enhance the device density per substrate unit area and the degree of freedom of the layout.

Furthermore, according to the fourth embodiment, by arranging the first power supply wiring layer and the second power supply wiring layer above or below the first semiconductor layer or the second semiconductor layer, a VDD potential and a VSS potential can be easily connected to both the first semiconductor layer and the second semiconductor layer. Accordingly, it is possible to enhance the degree of freedom of the layout.

### Modified Example of Fourth Embodiment

### (Configuration of Semiconductor Device)

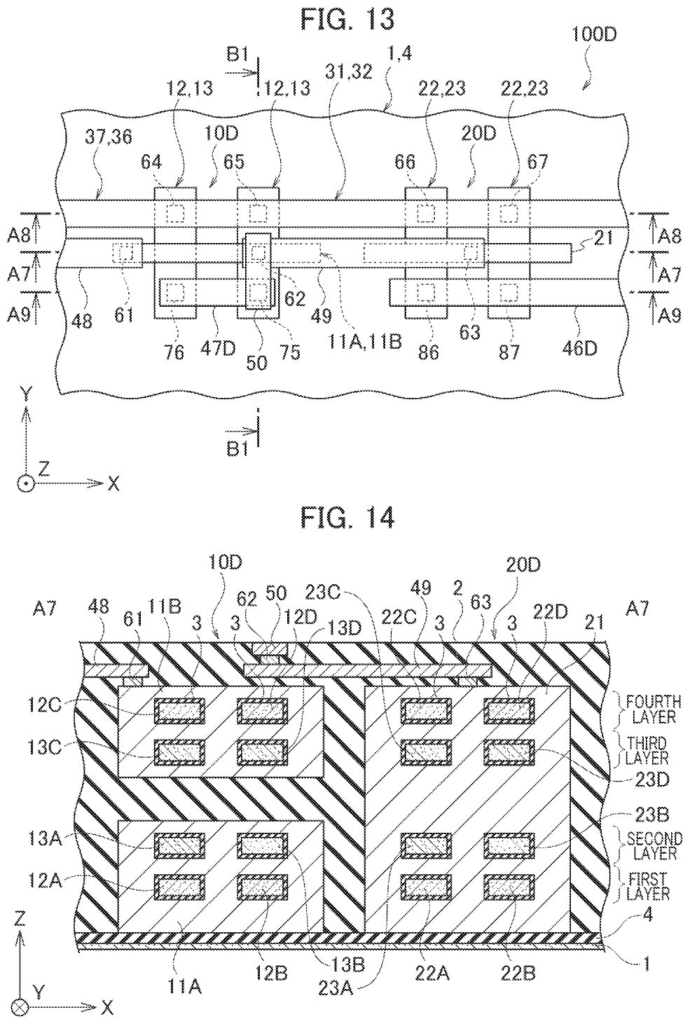

A description will be given regarding a semiconductor device 100D according to a modified example of the fourth embodiment. FIG. 13 is a top view and does not show the interlayer insulation film 2.

As shown in FIGS. 13 to 17, the semiconductor device 100D further includes a first power supply wiring layer (35 and 37), a second power supply wiring layer 36, fourth to sixth signal wiring layers (48 to 50), and vias (61 to 69 and 71 to 87) in addition to the elements of the semiconductor device 100B according to the third embodiment. The substrate 1 has an oxide film 4. Other configurations of the semiconductor device 100D are the same as those of the semiconductor device 100B according to the third embodiment, and therefore a description thereof is omitted. A first CMOS circuit 10D is another example of the first CMOS circuit 10. A second CMOS circuit 20D is another example of the second CMOS circuit 20.

As shown in FIG. 14, the fourth signal wiring layer 48 is arranged above the gate electrode 11B, for example. The fourth signal wiring layer 48 is electrically connected to the gate electrode 11B through the via 61, for example.

The fifth signal wiring layer 49 is arranged above the gate electrode 11B and the gate electrode 21, for example. The fifth signal wiring layer 49 is electrically connected to the gate electrode 21 through the via 63, for example.

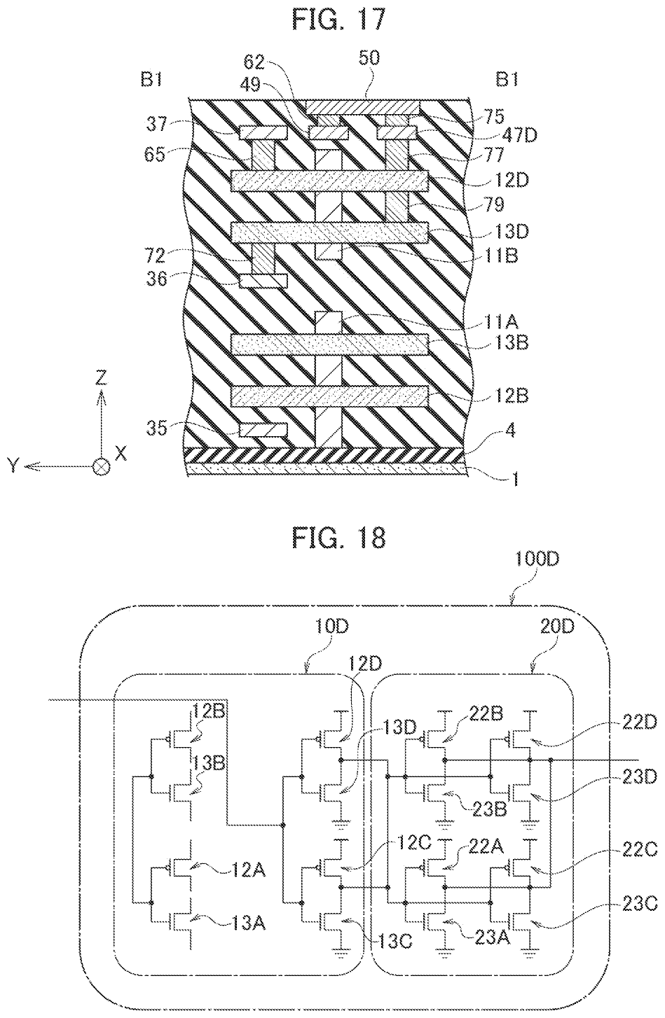

As shown in FIGS. 14 and 17, the sixth signal wiring layer 50 is arranged above the third signal wiring layer 47D and the fifth signal wiring layer 49, for example. The sixth signal wiring layer 50 is electrically connected to the fifth signal wiring layer 49 through the via 62, for example.

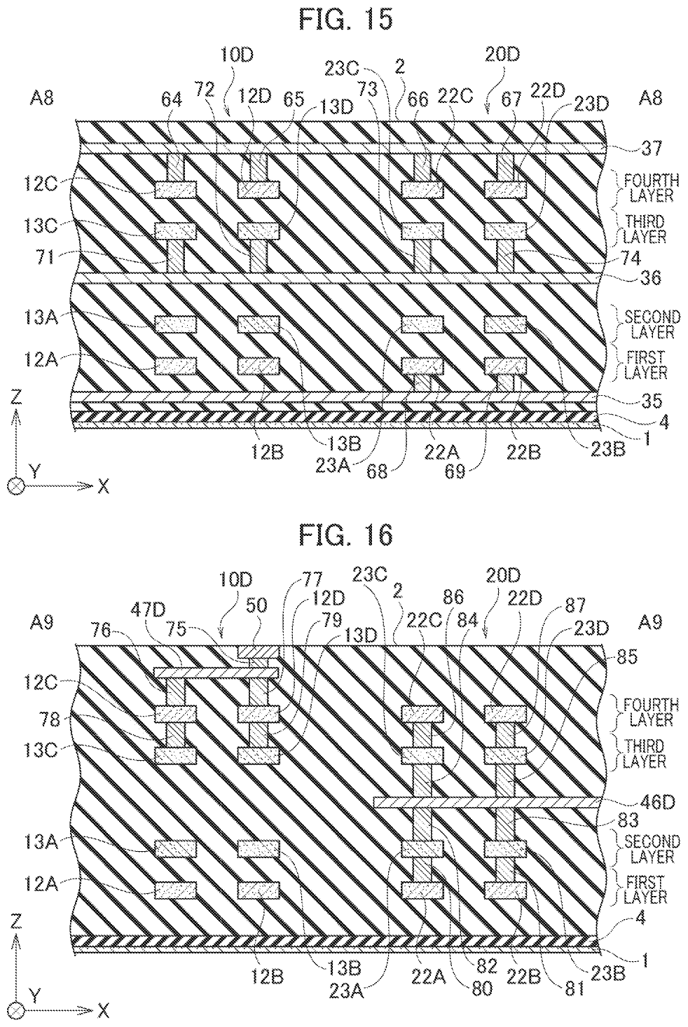

As shown in FIG. 15, the first power supply wiring layer 35 is electrically connected to the first source region 24 of the first semiconductor layer (22A and 22B) of the first layer through the vias (68 and 69), for example. Further, the first power supply wiring layer 37 is electrically connected to the first source region (14 and 24) of the first semiconductor layer (12C, 12D, 22C, and 22D) of the fourth layer through the vias (64 to 67), for example.

The second power supply wiring layer 36 is electrically connected to the second drain region (18 and 28) of the second semiconductor layer (13C, 13D, 23C, and 23D) of the third layer through the vias (71, 72, 73, and 74), for example.

As shown in FIG. 16, the second signal wiring layer 46D is electrically connected to the second source region 27 of the second semiconductor layer (23A and 23B) of the second layer through the vias (82 and 83), for example. Further, the second signal wiring layer 46D is electrically connected to the second source region 27 of the second semiconductor layer (23C and 23D) of the third layer through the vias (84 and 85), for example.

The second source region 27 of the second semiconductor layer (23A and 23B) of the second layer is electrically connected to the second drain region 28 of the first semiconductor layer (22A and 22B) of the first layer through the vias (80 and 81), for example. Further, the second source region 27 of the second semiconductor layer (23C and 23D) of the third layer is electrically connected to the second drain region 28 of the first semiconductor layer (22C and 22D) of the fourth layer through the vias (86 and 87), for example.

As shown in FIGS. 16 and 17, the third signal wiring layer 47D is electrically connected to the second drain region 28 of the first semiconductor layer (12C and 12D) of the fourth layer through the vias (76 and 77), for example. Further, the sixth signal wiring layer 50 is electrically connected to the third signal wiring layer 47D through the via 75, for example. The third signal wiring layer 47D is another example of the third signal wiring layer 47.

The second drain region 28 of the first semiconductor layer (12C and 12D) of the fourth layer is electrically connected to the first source region 24 of the second semiconductor layer (13C and 13D) of the third layer through the vias (78 and 79), for example.

An equivalent circuit of the semiconductor device 100D is represented by using the first CMOS circuit 10D and the second CMOS circuit 20D as shown in FIG. 18. The first semiconductor layer (12A and 12B) of the first layer and the second semiconductor layer (13A and 13B) of the second layer of the first CMOS circuit 10D are the same as those of the equivalent circuit of the semiconductor device 100 according to the first embodiment. Therefore, a description thereof is omitted.

The first CMOS circuit 10D can be represented by using a third circuit structure D in which the gate electrode 11B is electrically connected in common with the NMOS as the second conductive type MOS having the second semiconductor layer 13C of the third layer, and the PMOS as the first conductive type MOS having the first semiconductor layer 12C of the fourth layer. Further, the first CMOS circuit 10D can be represented by using a fourth circuit structure D in which the gate electrode 11B is electrically connected in common with the NMOS as the second conductive type MOS having the second semiconductor layer 13D of the third layer, and the PMOS as the first conductive type MOS having the first semiconductor layer 12D of the fourth layer. Furthermore, the circuit can be represented by using a circuit structure in which the gate electrodes 11B of the third circuit structure D and the fourth circuit structure D are electrically connected in common.

The gate electrode 11B can be represented by using a circuit structure in which an electrical connection is made to the fourth signal wiring layer 48 shown in FIG. 13.

The third circuit structure D and the fourth circuit structure D can be represented by using a circuit structure in which an electrical connection is made to the first power supply wiring layer (35 and 37) and the second power supply wiring layer 36 shown in FIG. 15. Further, the third circuit structure D and the fourth circuit structure D can be represented by using a circuit structure in which an electrical connection is made to the third signal wiring layer 47D, the sixth signal wiring layer 50, and the fifth signal wiring layer 49 shown in FIG. 13. The third signal wiring layer 47D, the sixth signal wiring layer 50, and the fifth signal wiring layer 49 can be represented by using a circuit structure in which an electrical connection is made to the gate electrode 21.

The second CMOS circuit 20D can be represented by using a fifth circuit structure D in which the gate electrode 21 is electrically connected in common with the PMOS as the first conductive type MOS having the first semiconductor layer 22A of the first layer, and the NMOS as the second conductive type MOS having the second semiconductor layer 23A of the second layer. In addition, the second CMOS circuit 20D can be represented by using a sixth circuit structure D in which the gate electrode 21 is electrically connected in common with the PMOS as the first conductive type MOS having the first semiconductor layer 22B of the first layer, and the NMOS as the second conductive type MOS having the second semiconductor layer 23B of the second layer. Furthermore, the circuit can be represented by using a circuit structure in which the gate electrodes 21 of the fifth circuit structure D and the sixth circuit structure D are electrically connected in common.

The second CMOS circuit 20D can be represented by using a seventh circuit structure D in which the gate electrode 21 is electrically connected in common with the NMOS as the second conductive type MOS having the second semiconductor layer 23C of the third layer, and the PMOS as the first conductive type MOS having the first semiconductor layer 22C of the fourth layer. In addition, the second CMOS circuit 20 can be represented by using an eighth circuit structure D in which the gate electrode 21 is electrically connected in common with the NMOS as the second conductive type MOS having the second semiconductor layer 23D of the third layer and the PMOS as the first conductive type MOS having the first semiconductor layer 22D of the fourth layer, for example. Further, the circuit can also be represented by using a structure in which the gate electrodes 21 of the seventh circuit structure D and the eighth circuit structure D are electrically connected in common. Furthermore, the circuit can be represented by using a structure in which the gate electrodes 21 of the fifth circuit structure D, the sixth circuit structure D, the seventh circuit structure D, and the eighth circuit structure D are electrically connected in common.

The fifth circuit structure D, the sixth circuit structure D, the seventh circuit structure D, and the eighth circuit structure D can be represented by using a circuit structure in which an electrical connection is made to the first power supply wiring layer (35 and 37) and the second power supply wiring layer 36 shown in FIG. 15. Further, the fifth circuit structure D, the sixth circuit structure D, the seventh circuit structure D, and the eighth circuit structure D can be represented by using a circuit structure in which an electrical connection is made to the second signal wiring layer 46D shown in FIG. 13.

### (Effect of Modified Example of Fourth Embodiment)

As described above, according to the modified example of the fourth embodiment, three or more layers of the first conductive type MOS and the second conductive type MOS are alternately stacked. Focusing on a certain first semiconductor layer or second semiconductor layer, a gate electrode is commonly connected with a first semiconductor layer or second semiconductor layer on or below the certain first semiconductor layer or second semiconductor layer. This can enhance the device density per substrate unit area and the degree of freedom of the layout.

Further, according to the modified example of the fourth embodiment, by arranging the first power supply wiring layer and the second power supply wiring layer above or below the first semiconductor layer or the second semiconductor layer, the VDD potential and the VSS potential can be easily connected to both the first semiconductor layer and the second semiconductor layer. Accordingly, it is possible to enhance the degree of freedom of the layout.

### Fifth Embodiment

### (Configuration of Semiconductor Device)

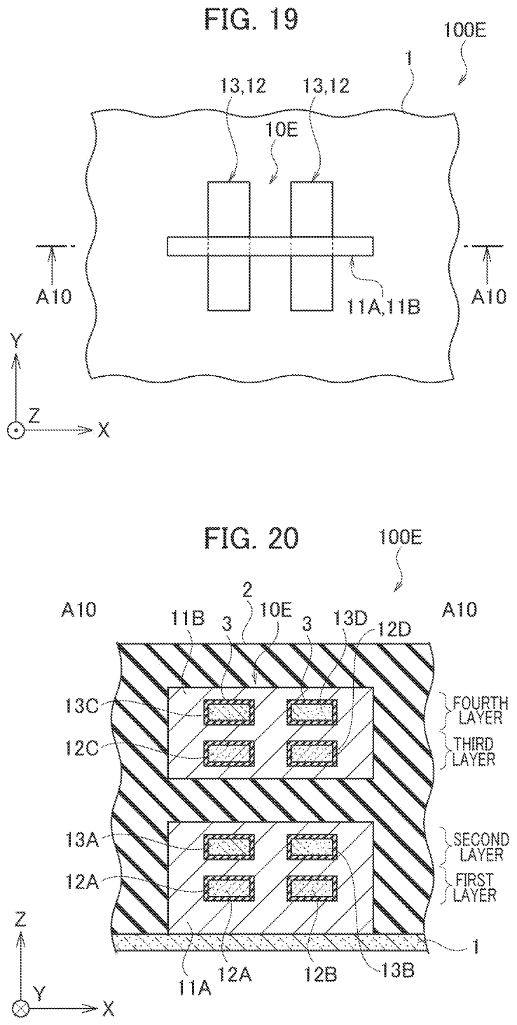

A semiconductor device 100E according to a fifth embodiment will be described. FIG. 19 is a top view and does not show the interlayer insulation film 2.

Hereafter, with reference to FIGS. 19 to 21, a description will be given regarding only the configuration of the semiconductor device 100E which differs from that of the semiconductor device of the first embodiment.

As shown in FIG. 19, the semiconductor device 100E includes a first semiconductor layer 12, a second semiconductor layer 13, and a gate electrode (11A and 11B). The semiconductor device 100E also has a first CMOS circuit 10E, which is formed of a combination of a first conductive type MOS and a second conductive type MOS. The semiconductor device 100E may have the substrate 1 and the interlayer insulation film 2. The first CMOS circuit 10E has the same structure as the first CMOS circuit 10 according to the first embodiment, and therefore a description thereof is omitted. The first CMOS circuit 10E is another example of the first CMOS circuit 10.

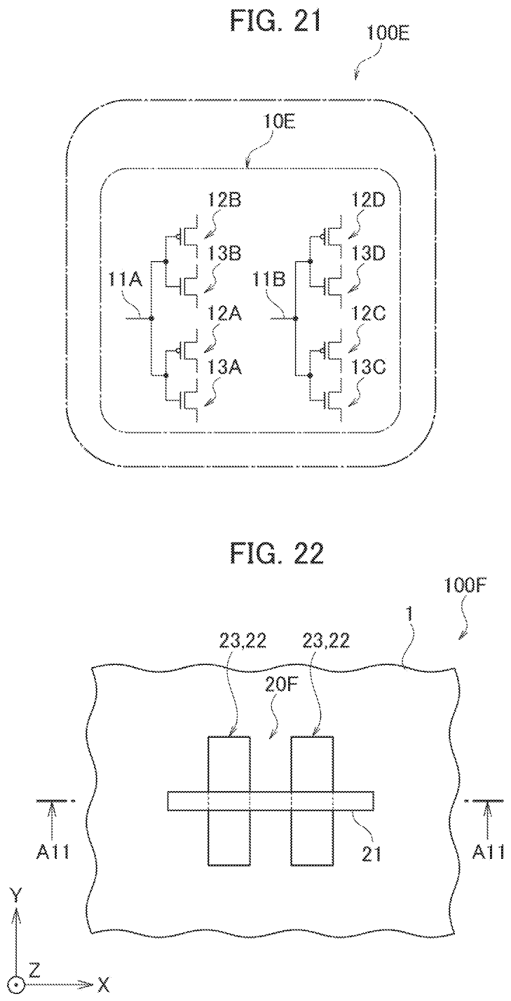

An equivalent circuit of the semiconductor device 100E is represented by using the first CMOS circuit 10E as shown in FIG. 21. The first CMOS circuit 10E has the same circuit structure as the first CMOS circuit 10 according to the first embodiment, and therefore a description thereof is omitted.

### (Effect of the Fifth Embodiment)

As described above, according to the fifth embodiment, three or more layers of the first conductive type MOS and the second conductive type MOS are alternately stacked. Focusing on a certain first semiconductor layer or second semiconductor layer, the gate electrode is commonly connected with a first semiconductor layer or second semiconductor layer on or below the certain first semiconductor layer or second semiconductor layer. This can enhance the device density per substrate unit area and the degree of freedom of the layout.

### Sixth Embodiment

### (Configuration of Semiconductor Device)

A semiconductor device 100F according to a sixth embodiment will be described. FIG. 22 is a top view and does not show the interlayer insulation film 2.

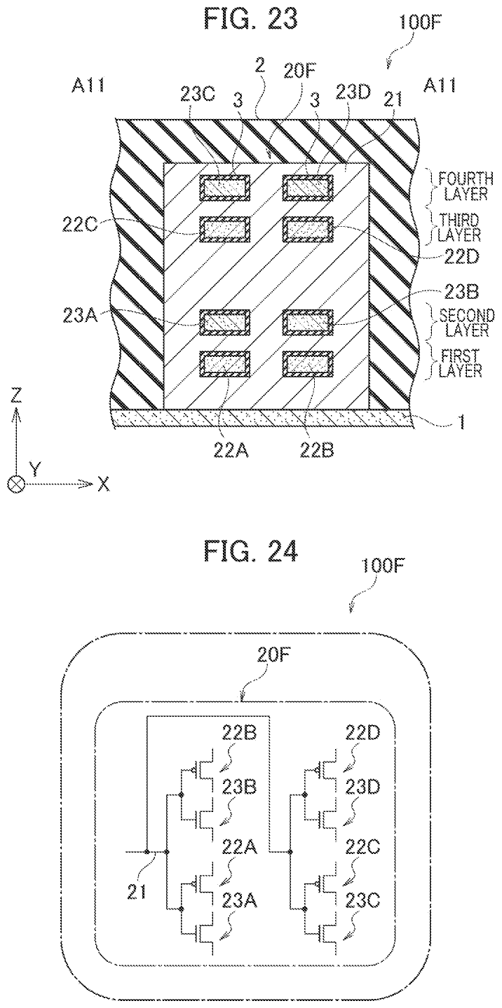

Hereafter, with reference to FIGS. 22 to 24, a description will be given regarding only the configuration of the semiconductor device 100F which differs from that of the semiconductor device of the first embodiment.

As shown in FIG. 22, the semiconductor device 100F includes a first semiconductor layer 22, a second semiconductor layer 23, and a gate electrode 21. The semiconductor device 100F also has a second CMOS circuit 20F, which is formed of a combination of a first conductive type MOS and a second conductive type MOS. The semiconductor device may also have the substrate 1 and the interlayer insulation film 2. The second CMOS circuit 20F has the same structure as the second CMOS circuit 20 according to the first embodiment, and therefore a description thereof is omitted. The second CMOS circuit 20F is another example of the second CMOS circuit 20.

An equivalent circuit of the semiconductor device 100F is represented by using the second CMOS circuit 20F as shown in FIG. 24. The second CMOS circuit 20F has the same structure as the second CMOS circuit 20 according to the first embodiment, and therefore a description thereof is omitted.

### (Effect of Sixth Embodiment)

As described above, according to the sixth embodiment, three or more layers of the first conductive type MOS and the second conductive type MOS are alternately stacked. Focusing on a certain first semiconductor layer or second semiconductor layer, the gate electrode is commonly connected with a first semiconductor layer or second semiconductor layer on or below the certain first semiconductor layer or second semiconductor layer. This can enhance the device density per substrate unit area and the degree of freedom of the layout.

### Seventh Embodiment

### (Configuration of Semiconductor Device)

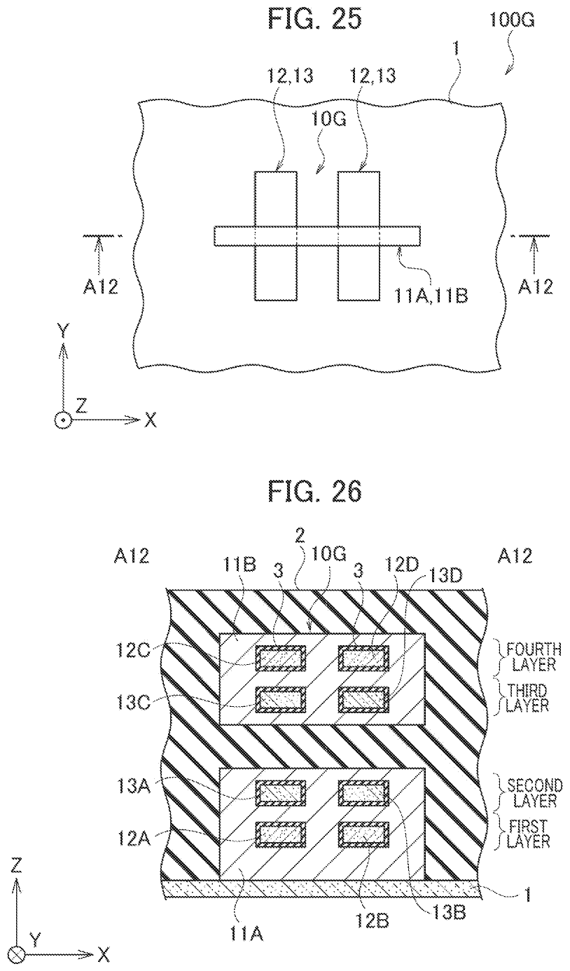

A semiconductor device 100G according to a seventh embodiment will be described. FIG. 25 is a top view and does not show the interlayer insulation film 2.

Hereafter, with reference to FIGS. 25 and 26, a description will be given regarding the configuration of the semiconductor device 100G which differs from that of the semiconductor device of the third embodiment.

As shown in FIG. 25, the semiconductor device 100G includes a first semiconductor layer 12, a second semiconductor layer 13, and a gate electrode (11A and 11B). The semiconductor device 100G also has a first CMOS circuit 10G, which is formed of a combination of a first conductive type MOS and a second conductive type MOS. The semiconductor device 100G may also have the substrate 1 and the interlayer insulation film 2. The first CMOS circuit 10G has the same structure as the first CMOS circuit 10B according to the third embodiment, and therefore a description thereof is omitted. The first CMOS circuit 10G is another example of the first CMOS circuit 10.

The first CMOS circuit 10G has the same structure as a first CMOS circuit 10E according to the fifth embodiment, and therefore a description thereof is omitted.

### (Effect of Seventh Embodiment)

As described above, according to the seventh embodiment, three or more layers of the first conductive type MOS and the second conductive type MOS are alternately stacked. Focusing on a certain first semiconductor layer or second semiconductor layer, the gate electrode is commonly connected with a first semiconductor layer or second semiconductor layer on or below the certain first semiconductor layer or second semiconductor layer. This can enhance the device density per substrate unit area and the degree of freedom of the layout.

### Eighth Embodiment

### (Configuration of Semiconductor Device)

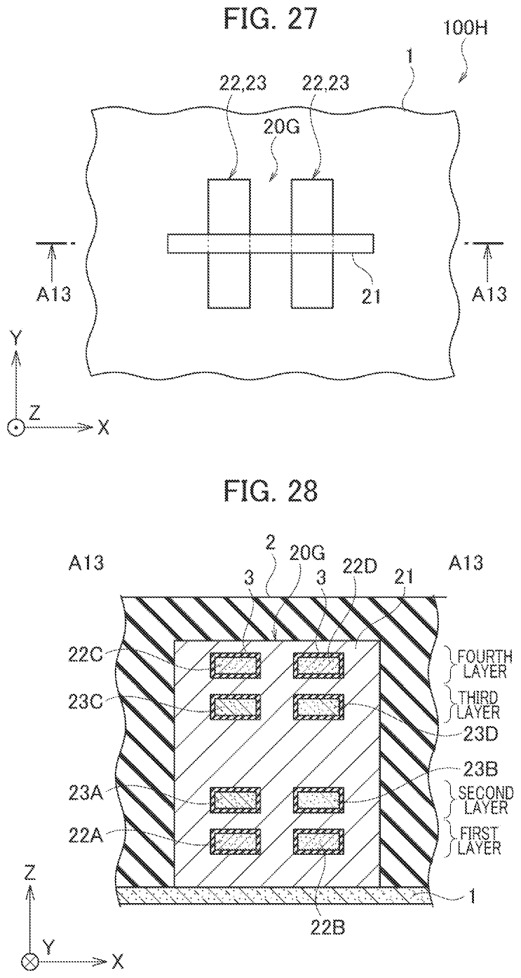

A semiconductor device 100H according to an eighth embodiment will be described. FIG. 27 is a top view and does not show the interlayer insulation film 2.

Hereinafter, with reference to FIGS. 27 and 28, a description will be given regarding the configuration of the semiconductor device 100H which differs from that of the semiconductor device of the third embodiment.

The semiconductor device 100H includes a first semiconductor layer 22, a second semiconductor layer 23, and a gate electrode 21 as shown in FIG. 27. The semiconductor device 100H also has a second CMOS circuit 20H, which is formed of a combination of a first conductive type MOS and a second conductive type MOS. The semiconductor device 100H may have the substrate 1 and the interlayer insulation film 2. The second CMOS circuit 20H has the same structure as the second CMOS circuit 20B according to the third embodiment, and therefore a description thereof is omitted. The second CMOS circuit 20H is another example of the second CMOS circuit 20.

The second CMOS circuit 20H has the same structure as the second CMOS circuit 20F according to the sixth embodiment, and therefore a description thereof is omitted.

### (Effect of Eighth Embodiment)

As described above, according to the eighth embodiment, three or more layers of a first conductive type MOS and a second conductive type MOS are alternately stacked. Focusing on a certain first semiconductor layer or second semiconductor layer, the gate electrode is commonly connected with a first semiconductor layer or second semiconductor layers on or below the certain first semiconductor layer or second semiconductor layer. This can enhance the device density per substrate unit area and the degree of freedom of the layout.

### Other Embodiments

While certain embodiments have been described, these embodiments have been presented by way of examples only, and are not intended to limit the scope of the inventions. Indeed, these novel embodiments described herein may be embodied in a variety of other forms; furthermore, various omissions, substitutions, and changes may be made without departing from the spirit of the inventions. These embodiments and variations thereof are included in the scope and the gist of the invention and are also included in the scope of the invention described in the claims and their equivalents.

A description has been given with the first conductive type MOS as a PMOS and the second conductive type MOS as an NMOS in the configurations of the semiconductor devices 100 to 100H according to the certain embodiments of the present invention, for example. However, alternatively, the first conductive type MOS may be an NMOS and the second conductive type MOS may be a PMOS. If the first conductive type MOS is an NMOS and the second conductive type MOS is a PMOS, the first power supply wiring layer (35 and 37) may be VSS wiring, for example, and the second power supply wiring layer 36 may be VDD wiring, for example.

The present embodiment includes various embodiments and the like that are not described herein. The following are examples of various aspects.

A semiconductor device including: a first semiconductor layer having a first source region, a first drain region, and a first channel region; a second semiconductor layer having a second source region, a second drain region, and a second channel region; a gate electrode that is formed to cover the first channel region and the second channel region with a gate insulating film interposed; and a first CMOS circuit that is formed of a combination of a first conductive type MOS having the first semiconductor layer and a second conductive type MOS having the second semiconductor layer, in which the first semiconductor layer is stacked in a (2n−1)^{th} layer, the second semiconductor layer is stacked in a 2n^{th} layer (1≤n≤N, N≥2, and n and N are integers), for a certain i (1≤i≤N), in the first CMOS circuit, the gate electrode is electrically connected in common with at least the first conductive type MOS of the first semiconductor layer of a (2i−1)^{th} layer and the second conductive type MOS of the second semiconductor layer of a 2i^{th} layer.

A semiconductor device including: a first semiconductor layer having a first source region, a first drain region, and a first channel region; a second semiconductor layer having a second source region, a second drain region, and a second channel region; a gate electrode that is formed to cover the first channel region and the second channel region with a gate insulating film interposed; and a second CMOS circuit that is formed of a combination of a first conductive type MOS having the first semiconductor layer and a second conductive type MOS having the second semiconductor layer, in which the first semiconductor layer is stacked in a (2n−1)^{th}, layer, the second semiconductor layer is stacked in a 2n^{th} layer (1≤n≤N, N≥2, and n and N are integers), and for a certain i (1≤i≤N), in the second CMOS circuit, the gate electrode is electrically connected in common with at least the second conductive type MOS of the second semiconductor layer of a 2i^{th} layer and the first conductive type MOS of the first semiconductor layer of a (2i+1)^{th} layer.

A semiconductor device including: a first semiconductor layer having a first source region, a first drain region, and a first channel region; a second semiconductor layer having a second source region, a second drain region, and a second channel region; a gate electrode that is formed to cover the first channel region and the second channel region with a gate insulating film interposed; and a first CMOS circuit that is formed of a combination of a first conductive type MOS having the first semiconductor layer and a second conductive type MOS having the second semiconductor layer, in which the first semiconductor layer is stacked in a (4n−3)^{th} layer and a 4n^{th} layer, the second semiconductor layer is stacked in a (4n−2)^{th} layer and a (4n−1)^{th} layer (1≤n≤N, N≥1, and n and N are integers), and for a certain i (1≤i≤N), in the first CMOS circuit, the gate electrode is electrically connected in common with at least the first conductive type MOS of the first semiconductor layer of a (4i−3)^{th} layer and the second conductive type MOS of the second semiconductor layer of a (4i−2)^{th} layer.

A semiconductor device including: a first semiconductor layer having a first source region, a first drain region, and a first channel region; a second semiconductor layer having a second source region, a second drain region, and a second channel region; a gate electrode that is formed to cover the first channel region and the second channel region with a gate insulating film interposed; and a second CMOS circuit that is formed of a combination of a first conductive type MOS having the first semiconductor layer and a second conductive type MOS having the second semiconductor layer, in which the first semiconductor layer is stacked in a (4n−3)^{th} layer and a 4n^{th} layer, the second semiconductor layer is stacked in a (4n−2)^{th} layer and a (4n−1)^{th} layer (1≤n≤N, N≥1, and n and N are integers), and for a certain i (1≤i≤N), in the second CMOS circuit, the gate electrode is electrically connected in common with at least the second conductive type MOS of the second semiconductor layer of a (4i−2)^{th} layer and the second conductive type MOS of the second semiconductor layer of a (4i−1)^{th} layer.

What is claimed is:

1. A semiconductor device comprising:
a first semiconductor layer having a first source region, a first drain region, and a first channel region;
a second semiconductor layer having a second source region, a second drain region, and a second channel region;
a gate electrode that is formed to cover the first channel region and the second channel region with a gate insulating film interposed; and
a first CMOS circuit and a second CMOS circuit each formed of a combination of a first conductive type MOS having the first semiconductor layer and a second conductive type MOS having the second semiconductor layer, wherein
the first semiconductor layer is stacked in a (2n−1)^{th} layer, the second semiconductor layer is stacked in a 2n^{th} layer (1≤n≤N, N≥2, and n and N are integers),
for a certain i (1≤n≤N), in the first CMOS circuit, the gate electrode is electrically connected in common with at least the first conductive type MOS of the first semiconductor layer of a (2i−1)^{th} layer and the second conductive type MOS of the second semiconductor layer of a 2i^{th} layer, and
in the second CMOS circuit, the gate electrode is electrically connected in common with at least the second conductive type MOS of the second semiconductor layer of the 2i^{th} layer and the first conductive type MOS of the first semiconductor layer of a (2i+1)^{th} layer.

2. The semiconductor device according to claim 1, wherein
a substrate is further provided below the first semiconductor layer and the second semiconductor layer.

3. The semiconductor device according to claim 2, wherein
the first semiconductor layer is stacked and arranged vertical to a surface of the substrate.

4. The semiconductor device according to claim 2, wherein
the second semiconductor layer is stacked and arranged vertical to a surface of the substrate.

5. The semiconductor device according to claim 2, wherein
the substrate comprises an oxide film.

6. The semiconductor device according to claim 1, wherein
the gate electrode is formed to cover the first channel region of a first layer and the second channel region of a second layer with the gate insulating film interposed.

7. The semiconductor device according to claim 1, wherein
the gate electrode is formed to cover the first channel region of a third layer and the second channel region of a fourth layer with the gate insulating film interposed.

8. The semiconductor device according to claim 1, wherein
the gate electrode is formed to cover the first channel region of a first layer and a third layer and the second channel region of a second layer and a fourth layer with the gate insulating film interposed.

9. The semiconductor device according to claim 1, wherein
the first CMOS circuit comprises:
the gate electrode that is formed to cover the first channel region of a first layer and the second channel region of a second layer with the gate insulating film interposed; and
the gate electrode that is formed to cover the first channel region of a third layer and the second channel region of a fourth layer with the gate insulating film interposed.

10. The semiconductor device according to claim 1, wherein
the second CMOS circuit comprises the gate electrode that is formed to cover the first channel region of a first layer and a third layer and the second channel region of a second layer and a fourth layer with the gate insulating film interposed.

11. The semiconductor device according to claim 1, wherein
the semiconductor device further comprises:
a first power supply wiring layer that is arranged below the first semiconductor layer in a direction perpendicular to the first semiconductor layer; and
a second power supply wiring layer that is arranged above the second semiconductor layer in a direction perpendicular to the second semiconductor layer.

12. A semiconductor device comprising:
a first semiconductor layer having a first source region, a first drain region, and a first channel region;
a second semiconductor layer having a second source region, a second drain region, and a second channel region;
a gate electrode that is formed to cover the first channel region and the second channel region with a gate insulating film interposed; and
a first CMOS circuit and a second CMOS circuit each formed of a combination of a first conductive type MOS having the first semiconductor layer and a second conductive type MOS having the second semiconductor layer, wherein
the first semiconductor layer is stacked in a (4n−3)^{th} layer and a 4n^{th} layer, and the second semiconductor layer is stacked in a (4n−2)^{th} layer and a (4n−1)^{th} layer (1≤n≤N, N≥1, and n and N are integers), and
for a certain i (1≤i≤N), in the first CMOS circuit, the gate electrode is electrically connected in common with at least the first conductive type MOS of the first semiconductor layer of a (4i−3)^{th} layer and the second conductive type MOS of the second semiconductor layer of a (4i−2)^{th} layer, and
in the second CMOS circuit, the gate electrode is electrically connected in common with at least the second conductive type MOS of the second semiconductor layer of the (4i−2)^{th} layer and the second conductive type MOS of the second semiconductor layer of a (4i−1)^{th} layer.

13. The semiconductor device according to claim 12, wherein
the gate electrode is formed to cover the first channel region of a first layer and the second channel region of a second layer with the gate insulating film interposed.

14. The semiconductor device according to claim 12, wherein
the gate electrode is formed to cover the first channel region of a fourth layer and the second channel region of a third layer with the gate insulating film interposed.

15. The semiconductor device according to claim 12, wherein
the first CMOS circuit comprises:
the gate electrode that is formed to cover the first channel region of a first layer and the second channel region of a second layer with the gate insulating film interposed; and
the gate electrode that is formed to cover the first channel region of a fourth layer and the second channel region of a third layer with the gate insulating film interposed.

16. The semiconductor device according to claim 12, wherein
the second CMOS circuit comprises the gate electrode that is formed to cover the first channel region of a first layer and a fourth layer and the second channel region of a second layer and a third layer with the gate insulating film interposed.

17. The semiconductor device according to claim 12, wherein
a substrate is further provided below the first semiconductor layer and the second semiconductor layer.

18. The semiconductor device according to claim 17, wherein
the substrate comprises an oxide film.

19. The semiconductor device according to claim 12, wherein
the semiconductor device further comprises a second power supply wiring layer that is interposed between the second semiconductor layer of a (4n−2)^{th} layer and the second semiconductor layer of a (4n−1)^{th} layer and is arranged in a direction perpendicular to the second semiconductor layer.
